(19) United States
(12) Patent Application Publication
(10) Pub. No.: US 2026/0090322 A1
(43) Pub. Date: Mar. 26, 2026

(54) EXHAUST SYSTEM CONTROL

(71) Applicant: Applied Materials, Inc., Santa Clara, CA (US)

(72) Inventors: Chandrakanth Gopularam, BANAGALORE (IN); Duc Dang Buckius, San Jose, CA (US)

(21) Appl. No.: 18/895,005

(22) Filed: Sep. 24, 2024

(51) Int. Cl. H01L 21/67; H01J 37/32

(52) U.S. Cl. CPC H10P 72/0604; H01J 37/32834; H01J 2237/3346

(57) ABSTRACT

Systems, methods, and apparatus including designs embodied in machine-readable media for exhaust control. One of the methods includes measuring an airflow through an exhaust path of a gas panel of a semiconductor processing system; determining whether the measured airflow is within a defined range; in response to determining that the measured airflow is outside of the defined range, selectively opening or closing the exhaust gate by an incremental amount.

### BACKGROUND

This specification relates to semiconductor systems, processes, and equipment.

Plasma etching can be used in semiconductor processing to fabricate integrated circuits. Integrated circuits can be formed from layer structures including multiple (e.g., two or more) layer compositions. Different etching gas chemistries, e.g., different mixtures of gases, can be used to form a plasma in the processing environment such that a given etching gas chemistry can have increased precision and higher selectivity for a layer composition to be etched.

### SUMMARY

This specification describes technologies for controlling exhaust flow in a multi-chamber substrate processing system. In particular, this specification describes motorized control valves to adjust the exhaust flow from each individual gas panel of the multi-chamber substrate processing system.

During a substrate processing operation, a particular mixture of process gases is provided by a gas panel and coupled to e.g., a gas delivery nozzle of a plasma-based processing chamber. For example, during operation a particular etching gas mixture is ignited into a plasma within the substrate processing chamber to etch specific portions of a substrate. Many of the process gasses may be hazardous such that any gas leakage from the gas panel needs to be exhausted away from the system, e.g., to a facility in which gases may be separated and recycled.

In a multi-chamber substrate processing system, multiple gas panels may have respective exhaust paths that feed to a single common exhaust line. Moreover, the air flow across each gas panel may have a specified flow rate range. The airflow through each gas panel depends in part on the distance from the exhaust source. Therefore, each gas panel can include a valve or gate that can be adjusted, e.g., opened or closed, to increase or decrease the air flow for the corresponding gas panel. In addition to being a function of distance from the exhaust source, the flow rate for a given gas panel may also depend on an operating status of an associated substrate processing chamber, e.g., a substrate processing chamber coupled to the single exhaust line may be in a service or maintenance state and not require any air flow so that the valve or gate for that gas panel may be closed. When the exhaust is closed, the system may also close inlets for process gases to the gas panel to prevent any accumulation of leaked gases.

This specification describes techniques for adjusting the valve or gate for individual gas panels based on air flow measurements at each gas panel exhaust with respect to a specified flow rate range. Furthermore, this specification describes techniques for providing an interlock between the exhaust valve or gate and gas inlets to the gas panel so that closing the exhaust also closes the gas inlet.

In general, one innovative aspect of the subject matter described in this specification can be embodied in a method for controlling an exhaust gate based on measured airflow. One of the methods includes measuring an airflow through an exhaust path of a gas panel of a semiconductor processing system; determining whether the measured airflow is within a defined range; in response to determining that the measured airflow is within the defined range, maintaining a position of an exhaust gate in the exhaust path; in response to determining that the measured airflow is outside of the defined range, selectively opening or closing the exhaust gate by an incremental amount.

In general, one innovative aspect of the subject matter described in this specification can be embodied in a system for controlling an exhaust gate based on measured airflow and further for precise percentage opening an interlocking with the condition of a service door. One of the systems includes two or more gas panels; two or more exhaust paths, each exhaust path coupling a respective gas panel with a common exhaust line; each exhaust path including: an airflow sensor; and a controllable exhaust gate, the controllable exhaust gate configured to move relative to the exhaust path to define a degree to which the exhaust path is open to the common exhaust line.

Other embodiments of these aspects include corresponding computer systems, and computer programs recorded on one or more computer storage devices, each configured to perform particular operations or actions. For a system of one or more computers to be configured to perform particular operations or actions means that the system has installed on it software, firmware, hardware, or a combination of them that in operation cause the system to perform the operations or actions. For one or more computer programs to be configured to perform particular operations or actions means that the one or more programs include instructions that, when executed by data processing apparatus, cause the apparatus to perform the operations or actions.

The subject matter described in this specification can be implemented in these and other embodiments so as to realize one or more of the following advantages. Exhaust gates for multiple gas panels coupled to a single exhaust line can be mechanically actuated and computer controlled based on airflow measurements at each exhaust gate. The open percentage of each exhaust gate for multiple processing chambers can be precisely and individually controlled to more accurately control the exhaust flow of each gas panel without manual intervention. This leads to less error in gas flow falling out of an acceptable range. Additionally, when one or more gas panels are in a service or maintenance state, the exhaust gates for other gas panels coupled to the same exhaust can be adjusted to balance the offline gas panels. Furthermore, closing an exhaust gate for a gas panel can automatically close the inlets of source gases to the gas panel, preventing a build up of excess gases, and in particular toxic and/or flammable gases, in the gas panel.

Although the remaining disclosure will describe gas panels as associated with a plasma processing chamber used in semiconductor manufacturing, it will be readily understood that the systems and methods disclosed are equally applicable to a variety of other processes as can occur in other systems in which multiple sources are coupled to a common exhaust line. Accordingly, the technology should not be considered to be so limited as for use with the described plasma processing chamber alone. It is to be understood that the technology is not limited to the equipment described, and processes discussed can be performed in any number of processing chambers and systems.

### BRIEF DESCRIPTION OF THE DRAWINGS

FIG. 1 is a block diagram of an example exhaust system.

FIG. 2 is a block diagram of an example exhaust control system.

FIG. 3 is a flow diagram of an example process for controlling an exhaust gate.

FIG. 4 is a flow diagram of an example process for managing exhaust flow and source gas inlets.

FIG. 5 is a block diagram of an example generic computing system.

Like reference numbers and designations in the various drawings indicate like elements.

### DETAILED DESCRIPTION

The present specification describes technologies for adjusting the gate or valve for individual gas panels based on air flow measurements at each gas panel exhaust with respect to a specified flow rate range. Furthermore, this specification describes techniques for providing an interlock between the exhaust valve or gate and gas inlets to the gas panel so that closing the exhaust also closes the gas inlets.

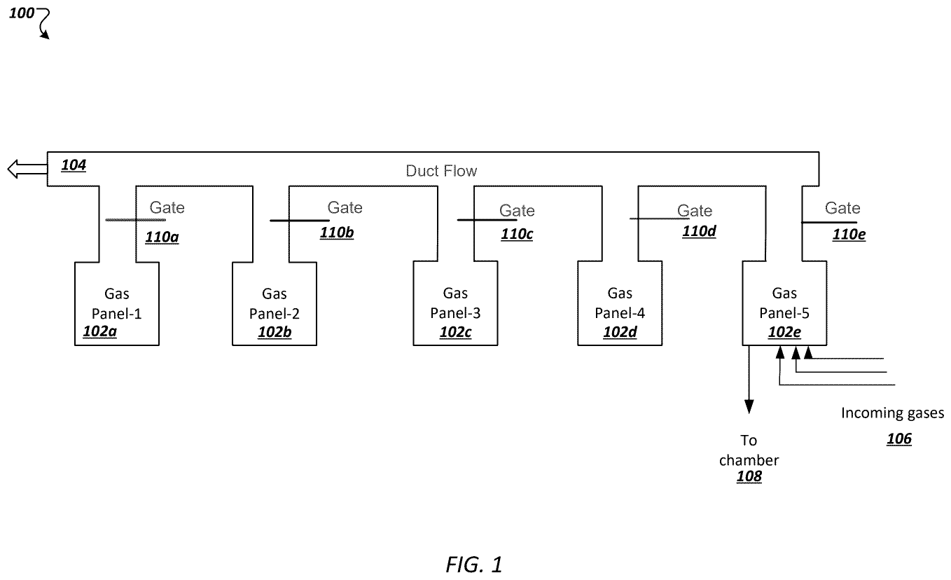

FIG. 1 is a block diagram of an example exhaust system 100. Exhaust system 100 includes gas panels 102a, 102b, 102c, 102d, and 102e. Although illustrated only with respect to gas panel 102e, each gas panel 102 can include one or more process gas sources coupled to input gas lines 106 and output 108, e.g., to a plasma processing chamber. The process gas sources can include inert gases, non-reactive gases, and reactive gases, as can be used for any number of suitable processes.

Each gas panel 102 can be part of a respective plasma-based processing chamber. Examples of process gases used in such a plasma-based processing chamber that can be provided by the gas panel 102 include, but are not limited to, hydrocarbon containing gases including methane, sulfur hexafluoride, silicon chloride, silicon tetrachloride, carbon tetrafluoride, hydrogen bromide. Process gases that can be provided by the gas panel 102 can also include, but are limited to, argon gas, chlorine gas, nitrogen, helium, or oxygen gas, sulfur dioxide, as well as any number of additional materials. Additionally, process gasses can include nitrogen, chlorine, fluorine, oxygen, or hydrogen containing gases including, for example, BCl₃, C₂F₄, C₄F₈, C₄F₆, CHF₃, CH₂F₂, CH₃F, NF₃, NH₃, CO₂, SO₂, CO, N₂, NO₂, N₂O, and H₂, among any number of additional suitable precursors.

A particular combination of process gases from process gas sources at the gas panel 102 can be combined prior to injection into the processing chamber to form one or more etching gas mixtures. For example, each gas panel 102 can include one or more process gas sources specific to oxide-based etching chemistries. In another example, each gas panel 102 can include one or more process gas sources specific to nitride-based etching chemistries.

Each gas panel 102 can include various valves, pressure regulators, and mass flow controllers arranged with respect to the gas sources to control the flow of the process gases from the sources. Valves can control the flow of the process gases from the sources from the gas panel to a gas distribution nozzle of the processing chamber, for example, through one or more gas lines 108. Operations of the valves, pressure regulators, and/or mass flow controllers can be controlled by a controller. The controller can be operably coupled to an electro-valve (EV) manifold of the gas panel to control actuation of one or more of the valves, pressure regulators, and/or mass flow controllers.

Leakage of process gases can occur within a given gas panel 102. For example, seals can break down or fail at various points leading to the release of different process gasses. To prevent a buildup of potentially hazardous process gases, each gas panel 102 is coupled to an exhaust line 104 that draws airflow across each gas panel along an exhaust path provided by the exhaust line 104. For example, the exhaust line 104 can be coupled to a fan that draws outside air through each gas panel and into exhaust line 104. Once evacuated, any exhausted process gases can be routed to a facility in which they are separated and recycled or otherwise disposed of.

In the exhaust system 100, each of the gas panels 102a-e are coupled to the exhaust line 104, thus they share a single common exhaust line. For example, ductwork can couple each gas panel to the common exhaust line. Each gas panel further includes a corresponding exhaust gate 110a, 110b, 110c, 110d, and 110e. The exhaust gates are used to maintain the exhaust flow rate across each gas panel within a specified range. For example, in some implementations, the flow rate across each gas panel should be maintained at 30 cubic feet per minute (CFM) plus/minus 5 CFM. However, without exhaust gates, the flow may be higher nearer to the exhaust source, e.g., across gas panel 102a, than at the far end from the exhaust source, e.g., across gas panel 102e. The exhaust gates 110 can be positioned to balance the airflow so that each gas panel has substantially the same airflow.

In the example shown in FIG. 1, exhaust gate 110a nearest to the exhaust source is set at 80% closed, the exhaust gate 110b is set to 60% closed, the exhaust gate 110c is set to 40% closed, the exhaust gate 110d is set to 20% closed, and the exhaust gate 110e is set to 0% closed (i.e., fully open). While these may be preset based on general distances from the exhaust source, during operation the gas flow across a given gas panel may vary due to different conditions and the operational status of the different processing chambers. Manual adjustment of the exhaust gages is cumbersome and error prone. This specification describes technologies to use mechanically controlled exhaust gates to more precisely and accurately position the exhaust gates to achieve a specified airflow across the gas panel.

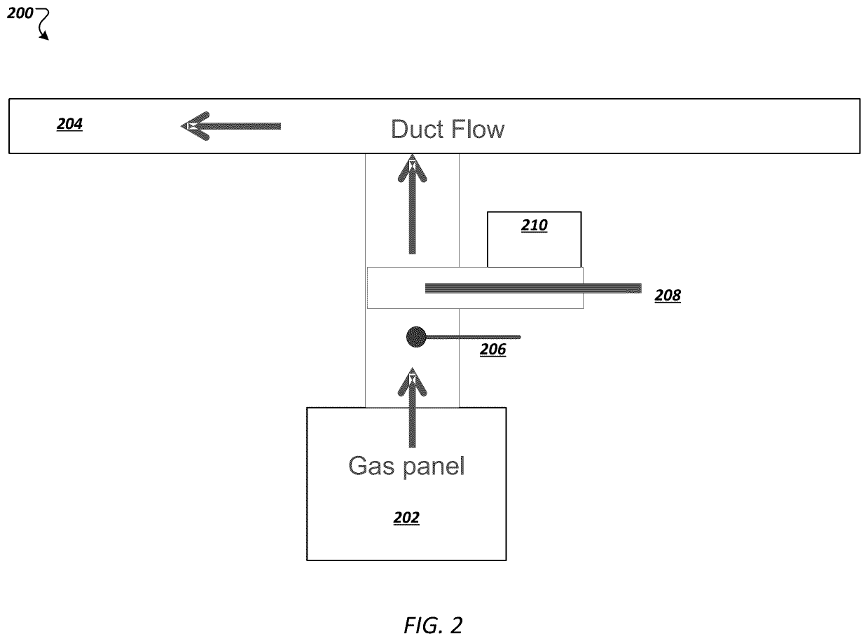

FIG. 2 is a block diagram of an example exhaust control system 200. In particular, the example exhaust control system 200 illustrates the exhaust control for a single gas panel 202 coupled to exhaust line 204. The flow path from the gas panel 202 to the exhaust line 204 includes a flow sensor 206, exhaust gate 208, and controller 210.

The flow sensor 206 can be any suitable flow sensor that can be inserted into the air flow path from the gas panel 202, e.g., a probe sensor positioned within the air flow path. For example, the flow sensor 206 can be a hot wire sensor, a moving vane meter, a pitot tube, or other suitable flow sensor. The exhaust gate 208 is configured to move perpendicularly to the flow airflow direction. The exhaust age 208 can be actuated to block some or all of the flow path. In some implementations, the exhaust gate 208 is a plate that can be moved laterally to block a portion of the air flow path, e.g., using a linear actuator controlled by controller 210. In some other implementations, the exhaust gate 208 is a valve that can be adjusted, e.g., by rotation, to block some or all the air flow path to the exhaust line 204. Such a valve can also be mechanically controlled by controller 210.

The controller 210 can include circuitry to control actuation of the exhaust gate 208, for example, in response to measurements by the flow sensor 206. The controller 210 can be used to independently control each exhaust control system or can be linked to other controllers for other gas panel exhaust control systems. Alternatively, the controller 210 may control actuation in response to instructions sent by a separate computing system, e.g., that determines when and by how much to adjust the exhaust gate in response to flow control measurements. Thus, the controllable exhaust gate is configured to move relative to the exhaust path to define a degree to which the exhaust path is open to the common exhaust line.

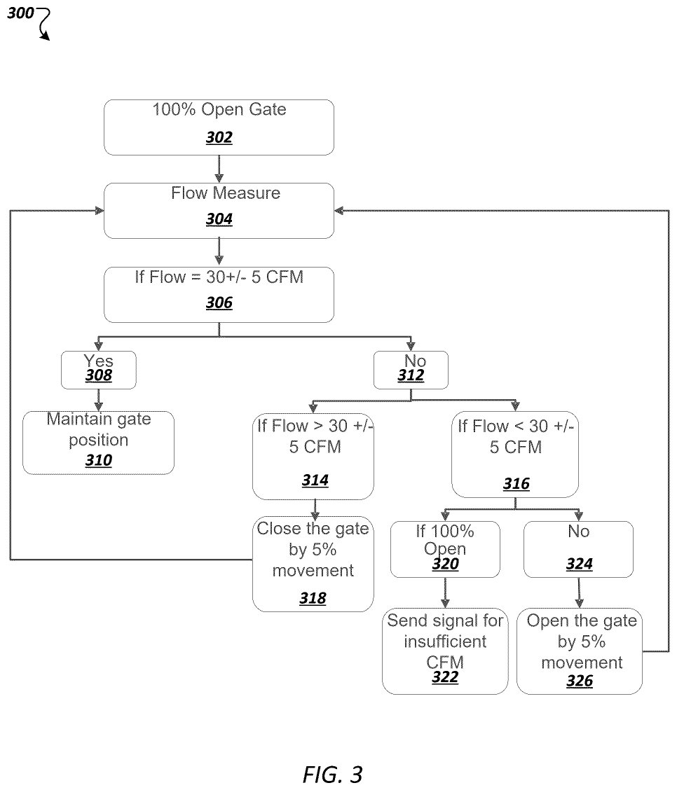

FIG. 3 is a flow diagram of an example process 300 for controlling an exhaust gate. For convenience, the process 300 will be described with respect to an exhaust control system or other computing system that performs at least some steps of the process. In particular, the process 300 is described with respect to controlling a single exhaust gate that is part of a system having multiple gas panels coupled to a single exhaust line.

The system can initialize with a fully open exhaust gate (302). In some alternative implementations, the exhaust gate can be manually set at a particular position corresponding to a closed percentage, e.g., according to a distance from an exhaust source.

The system measures the air flow (304). The air flow is measured, for example, using airflow sensor 204 of FIG. 2. The controller can receive a signal from the airflow sensor indicative of a particular airflow value. The controller can provide the airflow value to a control system, e.g., a computing device configured to control multiple exhaust systems.

The system determines if the measured airflow is within the specified airflow range (306). In some implementations, the specified airflow range is 30 +/−5 CFM.

However, other airflow ranges can be used depending on the particular exhaust requirements of the system.

In response to determining that the measured airflow is within the specified airflow range (308), the system determines that the exhaust gate is in the correct position (310).

In response to determining that the measured airflow is not within the specified airflow range (312), the system determines if the measured airflow is greater than the specified range (314) or less than the specified range (316).

If the measured airflow is greater than the specified range, e.g., greater than 35 CFM, the system closes the exhaust gate by a specified incremental amount, e.g., 5% (318). For example, the controller can be used to control an actuator that moves the exhaust gate by the specified amount. The system then loops back to the flow measurement step 304 and repeats the process.

If the measured airflow is less than the specified range, e.g., less than 25 CFM, and the exhaust gate is currently fully open (320), then the system sends an alert signal indicating insufficient airflow (322). In such a scenario maintenance or repair is likely needed to one or more components. In some implementations, the alert signal can trigger a shutdown process for a processing chamber associated with the exhaust gate. If the measured airflow is less than the specified range, e.g., less than 25 CFM, and the exhaust gate is not fully open (324), the system opens the exhaust gate by a specified incremental amount, e.g., 5% (326). For example, the controller can be used to control the actuator that moves the position of the exhaust gate by the specified amount.

In some implementations, the control system additionally considers the operational state of the gas panel and corresponding processing chamber. Based on the operational state, the system may further control the source of the process gases.

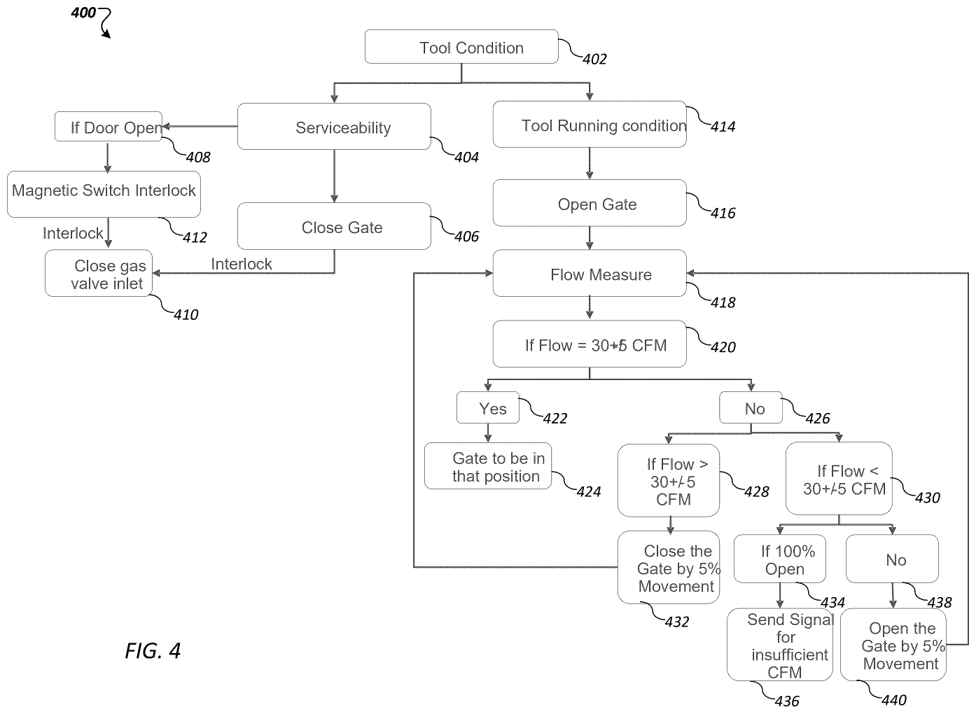

FIG. 4 is a flow diagram of an example process for managing exhaust flow and source gas inlets. For convenience, the process 400 will be described with respect to an exhaust control system or other computing system that performs at least some steps of the process. In particular, the process 400 is described with respect to controlling a single exhaust gate that is part of a system having multiple gas panels coupled to a single exhaust line.

The system identifies the status of the processing chamber (402). For example, the processing chamber can be in an operational state in which plasma etching is being actively performed or is in standby ready to perform operations. Alternatively, the processing chamber can be offline, for example, for performing service or other maintenance tasks.

If the status is identified as an offline state (404), e.g., a service or maintenance state, the system can fully close the exhaust gate (406). Concurrently, the system can identify whether a service door is open (408). For example, semiconductor processing systems can have access doors for maintenance or other service purposes. The access doors can incorporate a magnetic switch interlock that indicates whether the door is open or closed. This switch can interlock the door status (open/closed) with other actions including providing a signal to automatically close the exhaust gate when the door is open.

In response to the exhaust gate being fully closed, an interlock function can be activated that closes one or more process gas inlets (410). For example, there can be one or more gas lines leading to the gas panel. Controllable valves can be coupled to each of the one or more gas lines. The system can signal the valve controller(s) to close the valves in response to determining that the exhaust gate is fully closed. This prevents any leaking process gases from building up in the gas panel while there is no exhaust flow. Closing the inlet can conserve gases as well as reduce the power needs for the exhaust system.

Additionally, in response to determining that the service door is open, the interlock can again be triggered (412) to close the process gas inlets (410). For example, a magnetic switch can be associated with the door such that when it is opened, a signal is sent to the system to activate the interlock. In some implementations, in addition to the open door triggering the closure of the process gas input, it also triggers the closing of the exhaust gate. If the status is identified as in an operational state (414), the exhaust gate can be fully opened or set to a predetermined position, e.g., based on location relative to the exhaust source (416). The process then continues as described with respect to FIG. 3.

The system measures the air flow (418). The air flow is measured, for example, using airflow sensor 204 of FIG. 2. The controller can receive a signal from the airflow sensor indicative of a particular airflow value. The controller can provide the airflow value to a control system, e.g., a computing device configured to control multiple exhaust systems.

The system determines if the measured airflow is within the specified airflow range (420). In some implementations, the specified airflow range is 30 +/−5 CFM. However, other airflow ranges can be used depending on the exhaust requirements.

In response to determining that the measured airflow is within the specified airflow range (422), the system determines that the exhaust gate is in the correct position (424).

In response to determining that the measured airflow is not within the specified airflow range (426), the system determines if the measured airflow is greater than the specified range (428) or less than the specified range (430).

If the measured airflow is greater than the specified range, e.g., greater than 35 CFM, the system closes the exhaust gate by a specified incremental amount, e.g., 5% (432). For example, the controller can be used to control an actuator that moves the exhaust gate by the specified amount. The system then loops back to the flow measurement step 418 and repeats the process.

If the measured airflow is less than the specified range, e.g., less than 25 CFM, and the exhaust gate is currently fully open (434), then the system sends an alert signal indicating insufficient airflow (436). In such a scenario maintenance or repair is likely needed to one or more components. In some implementations, the alert signal can trigger a shutdown process for a processing chamber associated with the exhaust gate.

If the measured airflow is less than the specified range, e.g., less than 25 CFM, and the exhaust gate is not fully open (438), the system opens the exhaust gate by a specified incremental amount, e.g., 5% (440). For example, the controller can be used to control the actuator that moves the position of the exhaust gate with respect to the airflow path by the specified amount. The system then loops back to the flow measurement step 418 and repeats the process.

When the exhaust gate is fully closed, the exhaust gate positions for other gas panels coupled to the same exhaust line may need to be adjusted due to changes in the airflow across one or more of the gas panels. This adjustment can occur for each exhaust gate as described with respect to FIG. 3 or FIG. 4.

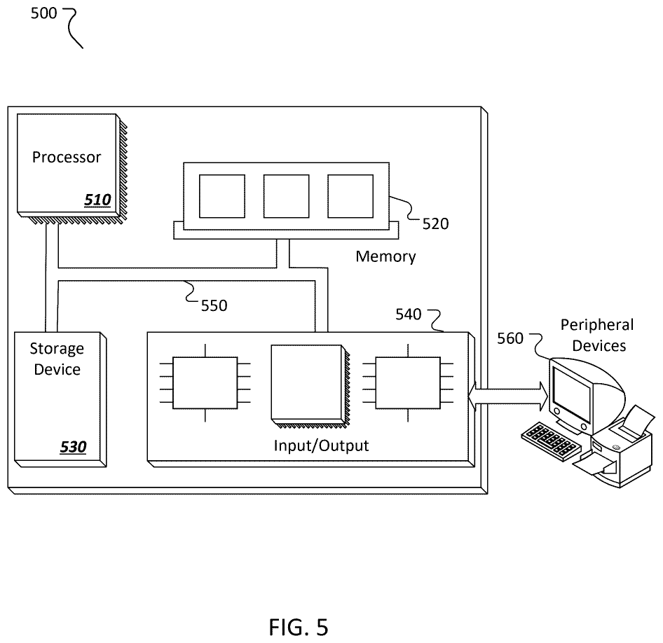

FIG. 5 is a block diagram of an example computer system 500 that can be used to perform operations described above. The system 500 includes a processor 510, a memory 520, a storage device 530, and an input/output device 540. Each of the components 510, 520, 530, and 540 can be interconnected, for example, using a system bus 550. The processor 510 is capable of processing instructions for execution within the system 500. In one implementation, the processor 510 is a single-threaded processor. In another implementation, the processor 510 is a multi-threaded processor. The processor 510 is capable of processing instructions stored in the memory 520 or on the storage device 530.

The memory 520 stores information within the system 2300. In one implementation, the memory 520 is a computer-readable medium. In one implementation, the memory 520 is a volatile memory unit. In another implementation, the memory 520 is a non-volatile memory unit.

The storage device 530 is capable of providing mass storage for the system 500. In one implementation, the storage device 530 is a computer-readable medium. In various different implementations, the storage device 530 can include, for example, a hard disk device, an optical disk device, a storage device that is shared over a network by multiple computing devices (e.g., a cloud storage device), or some other large capacity storage device.

The input/output device 540 provides input/output operations for the system 500. In one implementation, the input/output device 540 can include one or more of a network interface device, e.g., an Ethernet card, a serial communication device, e.g., and RS-232 port, and/or a wireless interface device, e.g., and 802.11 card. In another implementation, the input/output device can include driver devices configured to receive input data and send output data to peripheral devices 560, e.g., keyboard, printer and display devices. Other implementations, however, can also be used, such as mobile computing devices, mobile communication devices, set-top box television client devices, etc.

Although an example processing system has been described in FIG. 5, implementations of the subject matter and the functional operations described in this specification can be implemented in other types of digital electronic circuitry, or in computer software, firmware, or hardware, including the structures disclosed in this specification and their structural equivalents, or in combinations of one or more of them.

Aspects of the subject matter and the actions and operations described in this specification, for example, computing devices such as controller and processes performed by controller such as controlling of exhaust gates and process gas inlets, can be implemented in digital electronic circuitry, in tangibly-embodied computer software or firmware, in computer hardware, including the structures disclosed in this specification and their structural equivalents, or in combinations of one or more of them.

The subject matter and the actions and operations described in this specification can be implemented as or in one or more computer programs, e.g., one or more modules of computer program instructions, encoded on a computer program carrier, for execution by, or to control the operation of, data processing apparatus. The carrier can be a tangible non-transitory computer storage medium. Alternatively, or in addition, the carrier can be an artificially-generated propagated signal, e.g., a machine-generated electrical, optical, or electromagnetic signal, which is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

The term “data processing apparatus” encompasses all kinds of apparatus, devices, and machines for processing data, including by way of example a programmable processor, a computer, or multiple processors or computers. Data processing apparatus can include special-purpose logic circuitry, e.g., an FPGA (field programmable gate array), an ASIC (application-specific integrated circuit), or a GPU (graphics processing unit). The apparatus can also include, in addition to hardware, code that creates an execution environment for computer programs, e.g., code that constitutes processor firmware, a protocol stack, a database management system, an operating system, or a combination of one or more of them.

A computer program can be written in any form of programming language, including compiled or interpreted languages, or declarative or procedural languages; and it can be deployed in any form, including as a stand-alone program, e.g., as an app, or as a module, component, engine, subroutine, or other unit suitable for executing in a computing environment, which environment can include one or more computers interconnected by a data communication network in one or more locations.

A computer program can, but need not, correspond to a file in a file system. A computer program can be stored in a portion of a file that holds other programs or data, e.g., one or more scripts stored in a markup language document, in a single file dedicated to the program in question, or in multiple coordinated files, e.g., files that store one or more modules, sub-programs, or portions of code.

The processes and logic flows described in this specification can be performed by one or more computers executing one or more computer programs to perform operations by operating on input data and generating output. The processes and logic flows can also be performed by special-purpose logic circuitry, e.g., an FPGA, an ASIC, or a GPU, or by a combination of special-purpose logic circuitry and one or more programmed computers.

Computers suitable for the execution of a computer program can be based on general or special-purpose microprocessors or both, and any other kind of central processing unit. Generally, a central processing unit will receive instructions and data from a read-only memory or a random-access memory or both. The essential elements of a computer are a central processing unit for executing instructions and one or more memory devices for storing instructions and data. The central processing unit and the memory can be supplemented by, or incorporated in, special-purpose logic circuitry.

Generally, a computer will also include, or be operatively coupled to, one or more mass storage devices, and be configured to receive data from or transfer data to the mass storage devices. The mass storage devices can be, for example, magnetic, magneto-optical, or optical disks, or solid-state drives. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

While this specification contains many specific implementation details, these should not be construed as limitations on the scope of what is being claimed, which is defined by the claims themselves, but rather as descriptions of features that can be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features can be described above as acting in certain combinations and even initially be claimed as such, one or more features from a claimed combination can in some cases be excised from the combination, and the claim can be directed to a subcombination or variation of a subcombination.

Similarly, while operations are depicted in the drawings and recited in the claims in a particular order, this by itself should not be understood as requiring that such operations be performed in the particular order shown or in sequential order, or that all illustrated operations be performed, to achieve desirable results. In certain circumstances, multitasking and parallel processing can be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing can be advantageous.

What is claimed is:

1. A method comprising:
measuring an airflow through an exhaust path of a gas panel of a semiconductor processing system;
determining whether the measured airflow is within a defined range;
in response to determining that the measured airflow is within the defined range, maintaining a position of an exhaust gate in the exhaust path; and
in response to determining that the measured airflow is outside of the defined range, selectively opening or closing the exhaust gate by an incremental amount.

2. The method of claim 1, wherein determining that the measured airflow is outside of the defined range comprises determining that the measured airflow is greater than the defined range, and in response incrementally closing an exhaust gate in the exhaust path by a first amount.

3. The method of claim 1, wherein determining that the measured airflow is outside of the defined range comprises determining that the measured airflow is less than the defined range, and in response to determining that the exhaust gate is not fully opened, opening the exhaust gate in the exhaust path by a second amount.

4. The method of claim 1, further comprising:
in response to determining that the measured airflow is within the defined range, maintaining a position of the exhaust gate in the exhaust path.

5. The method of claim 1, wherein determining that the measured airflow is outside of the defined range comprises determining that the measured airflow is less than the defined range and in response to determining that the exhaust gate is fully opened, sending an alert signal indicating insufficient airflow.

6. The method of claim 1, further comprising:
determining a state of the semiconductor processing system; and
in response to determining that the semiconductor processing system is in an offline state, fully closing the exhaust gate.

7. The method of claim 6, wherein in response to fully closing the exhaust gate, engaging an interlock that closes a process gas inlet to the gas panel.

8. The method of claim 6, wherein in response to determining that a service door is opened, engaging an interlock that closes a process gas inlet to the gas panel.

9. A system comprising:
a plurality of gas panels;
a plurality of exhaust paths, each exhaust path coupling a respective gas panel with a common exhaust line;
each exhaust path comprising:
an airflow sensor; and
a controllable exhaust gate, the controllable exhaust gate configured to move relative to the exhaust path to define a degree to which the exhaust path is open to the common exhaust line.

10. The system of claim 9, wherein the controllable exhaust gate further comprises an actuator that mechanically moves the exhaust gate within the airflow path of the exhaust path in response to control signals received from a controller.

11. The system of claim 9, wherein the controller signals an actuator to move the exhaust gate to a position that provides a specified airflow rate from the gas panel.

12. The system of claim 9, further comprising:
a plurality of source gas inlet controls, each source gas inlet control configured to open or close source gas lines to a corresponding gas panel.

13. The system of claim 12, wherein the source gas inlet controls are configured to close source gas lines in response to a corresponding exhaust gate being fully closed.

14. One or more computer-readable storage media encoded with instructions that, when executed by one or more computers, cause the one or more computers to perform operations comprising:
measuring an airflow through an exhaust path of a gas panel of a semiconductor processing system;
determining whether the measured airflow is within a defined range;
in response to determining that the measured airflow is within the defined range, maintaining a position of an exhaust gate in the exhaust path; and
in response to determining that the measured airflow is outside of the defined range, selectively opening or closing the exhaust gate by an incremental amount.

15. The computer-readable storage media of claim 14, wherein determining that the measured airflow is outside of the defined range comprises determining that the measured airflow is greater than the defined range, and in response incrementally closing an exhaust gate in the exhaust path by a first amount.

16. The computer-readable storage media of claim 14, wherein determining that the measure airflow is outside of the defined range comprises determining that the measured airflow is less than the defined range, and in response to determining that the exhaust gate is not fully opened, opening the exhaust gate in the exhaust path by a second amount.

17. The computer-readable storage media of claim 14, further comprising:
in response to determining that the measured airflow is within the defined range, maintaining a position of the exhaust gate in the exhaust path.

18. The computer-readable storage media of claim 14, wherein determining that the measured airflow is outside of the defined range comprises determining that the measured airflow is less than the defined range and in response to determining that the exhaust gate is fully opened, sending an alert signal indicating insufficient airflow.

19. The computer-readable storage media of claim 14, further comprising:
determining a state of the semiconductor processing system; and
in response to determining that the semiconductor processing system is in an offline state, fully closing the exhaust gate.

20. The computer-readable storage media of claim 19, wherein in response to fully closing the exhaust gate, engaging an interlock that closes a process gas inlet to the gas panel.
